(19) United States
(12) Patent Application Publication
(10) Pub. No.: US 2025/0130772 A1
(43) Pub. Date: Apr. 24, 2025

(54) NEURAL NETWORK CIRCUIT AND ARITHMETIC METHOD

(71) Applicant: Sony Group Corporation, Tokyo (JP)

(72) Inventor: Hiroyuki Katchi, Tokyo (JP)

(21) Appl. No.: 18/835,702

(22) PCT Filed: Mar. 7, 2023
(86) PCT No.: PCT/JP2023/008484

§ 371 Date: Aug. 2, 2024

(30) Foreign Application Priority Data
Mar. 14, 2022 (JP) 2022-039095

(51) Int. Cl. G06F 7/544; G06N 3/063; H03H 17/02

(52) U.S. Cl. CPC G06F 7/5443; G06N 3/063; H03H 17/02

(57) ABSTRACT

Downsized division circuitry is disclosed. In one example, a coefficient holding unit holds a coefficient of a filter used for a convolution operation. A multiplier data holding unit holds, as multiplier data, an inverse number of the number of elements of a pooling window used for an average pooling operation. An input data holding unit holds input data of the convolution operation and the average pooling operation. A control unit performs control to input the input data held in the input data holding unit and the coefficient held in the coefficient holding unit to a product-sum operator for a product-sum calculation for the convolution operation, and performs control to input the input data held in the input data holding unit and the multiplier data held in the multiplier data holding unit to the product-sum operator and cause the product-sum operator to perform a product-sum operation for the average pooling operation.

### FIELD

The present disclosure relates to a neural network circuit and an arithmetic method.

### BACKGROUND

A deep neural network (DNN), which is an example of deep learning, is becoming a leading technology for artificial intelligence (AI) in recent years. The DNN includes a convolution layer, a pooling layer, and the like. The convolution layer is a layer that performs a convolution operation. This convolution operation is an operation of locally extracting a feature amount from input data. Further, the pooling layer is a layer that mainly performs an operation of reducing input data such as a result of a convolution operation. As this calculation, an average pooling operation for reducing by calculating an average value of input data is used. In this average pooling operation, it is necessary to perform division when calculating an average value. A divider that performs this division has a large circuit scale, and thus there is a problem that the size of a neural network circuit increases.

Accordingly, a neural network circuit that performs division by shift operation has been proposed (see, for example, Patent Literature 1).

### CITATION LIST

### Patent Literature

Patent Literature 1: JP 2021-168095 A

### SUMMARY

### Technical Problem

However, in the above-described conventional technique, there is a problem that the divisor is limited to a value of a power of 2.

Therefore, the present disclosure proposes a neural network circuit and an arithmetic method including a division unit that corresponds to any divisor and prevents an increase in circuit scale.

### Solution to Problem

A neural network circuit according to the present disclosure includes: a coefficient holding unit that holds a coefficient of a filter used for a convolution operation; a multiplier data holding unit that holds, as multiplier data, an inverse number of a number of elements of a pooling window used for an average pooling operation; an input data holding unit that holds input data of the convolution operation and the average pooling operation; a product-sum operator that performs a product-sum operation; and a control unit that performs control to input the input data held in the input data holding unit and the coefficient held in the coefficient holding unit to the product-sum operator and cause the product-sum operator to perform a product-sum calculation for the convolution operation, and performs control to input the input data held in the input data holding unit and the multiplier data held in the multiplier data holding unit to the product-sum operator and cause the product-sum operator to perform a product-sum operation for the average pooling operation.

### BRIEF DESCRIPTION OF DRAWINGS

FIG. 1 is a diagram illustrating a configuration example of a neural network circuit according to an embodiment of the present disclosure.

FIG. 2 is a diagram illustrating a configuration example of an arithmetic unit according to a first embodiment of the present disclosure.

FIG. 3A is a diagram illustrating an example of a convolution operation according to the embodiment of the present disclosure.

FIG. 3B is a diagram illustrating an example of the convolution operation according to the embodiment of the present disclosure.

FIG. 3C is a diagram illustrating an example of the convolution operation according to the embodiment of the present disclosure.

FIG. 4 is a diagram illustrating an example of an average pooling operation according to the embodiment of the present disclosure.

FIG. 5 is a diagram illustrating an example of a processing procedure of the convolution operation according to the first embodiment of the present disclosure.

FIG. 6 is a diagram illustrating an example of a processing procedure of the average pooling operation according to the first embodiment of the present disclosure.

FIG. 7 is a diagram illustrating a configuration example of a neural network circuit according to a second embodiment of the present disclosure.

### DESCRIPTION OF EMBODIMENTS

Hereinafter, an embodiment of the present disclosure will be described in detail with reference to the drawings. The description will be given in the following order. Note that in each of the following embodiments, the same parts are denoted by the same reference numerals, and redundant description will be omitted.
1. First Embodiment

### 2. Second Embodiment

### 1. First Embodiment

### [Configuration of Neural Network Circuit]

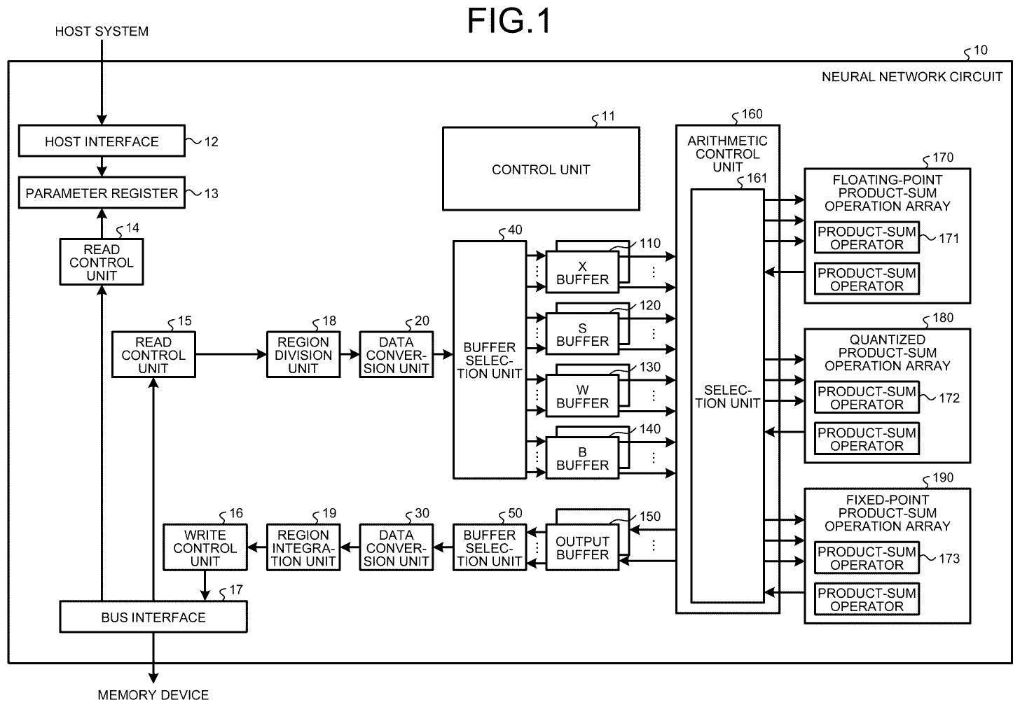

FIG. 1 is a diagram illustrating a configuration example of a neural network circuit according to an embodiment of the present disclosure. The drawing is a block diagram illustrating a configuration example of the neural network circuit 10. The neural network circuit 10 is a circuit that performs an operation related to DNN such as a convolution operation or an average pooling operation. The neural network circuit 10 performs a process of calculating data read from a memory device and writing an operation result to the memory device. As the data processed by the neural network circuit 10, for example, data having a two-dimensional array structure such as image data is assumed.

The neural network circuit 10 includes a control unit 11, a host interface 12, a parameter register 13, read control units 14 and 15, a write control unit 16, a bus interface 17, a region division unit 18, and a region integration unit 19. The neural network circuit 10 further includes data conversion units 20 and 30, buffer selection units 40 and 50, an X buffer 110, an S buffer 120, a W buffer 130, a B buffer 140, an output buffer 150, and an arithmetic control unit 160. The neural network circuit 10 further includes a floating-point product-sum operation array 170, a quantized product-sum operation array 180, and a fixed-point product-sum operation array 190.

The control unit 11 controls the entire neural network circuit 10. The control unit 11 performs control on the basis of a parameter held in a parameter register 13 described later. The control unit 11 can include, for example, a central processing unit (CPU), a microcomputer, a state machine circuit, and the like.

The host interface 12 exchanges data with the host system. The bus interface 17 exchanges data with a memory device via a bus.

The parameter register 13 holds parameters in operation. Parameters are input to the parameter register 13 from the memory device and the host system.

The read control unit 14 and the read control unit 15 perform control to read data from the memory device. The read control unit 14 outputs the read data to the parameter register 13. The read control unit 15 outputs the read data to the region division unit 18. The region division unit 18 divides input data.

The region division unit 18 divides the input data having a read width defined by the bus interface 17 into a minimum width when the input data is stored in the X buffer 110 or the like. For example, the region division unit 18 can divide the input data every 8 bits. The region division unit 18 outputs the divided data to the data conversion unit 20.

The data conversion unit 20 converts a data format. The data conversion unit 20 converts the input data into a format applied in the product-sum operation in the subsequent stage.

The buffer selection unit 40 selects the X buffer 110, the S buffer 120, the W buffer 130, and the B buffer 140 to be described later. The buffer selection unit 40 inputs data from the data conversion unit 20 to the selected X buffer 110 or the like.

The X buffer 110 holds data to be subjected to a convolution operation. A plurality of X buffers 110 is arranged in accordance with the number of channels of the input data.

The S buffer 120 holds data for improving processing efficiency of the arithmetic control unit 160 and a selection unit 161. A plurality of S buffers 120 is arranged in accordance with the number of channels of the input data.

The W buffer 130 holds coefficients of a filter in a convolution operation. A plurality of W buffers 130 is arranged in accordance with the number of channels of the input data.

The B buffer 140 holds a bias value in the convolution operation. A plurality of B buffers 140 is arranged in accordance with the number of channels of the input data.

The X buffer 110, the S buffer 120, the W buffer 130, and the B buffer 140 can be constituted by semiconductor memories.

The arithmetic control unit 160 controls input and output of product-sum operation. The arithmetic control unit 160 includes a selection unit 161. The selection unit 161 selects the X buffer 110, the S buffer 120, the W buffer 130, and the B buffer 140, and reads data from the selected X buffer 110 or the like. Further, the selection unit 161 selects any one of the floating-point product-sum operation array 170, the quantized product-sum operation array 180, and the fixed-point product-sum operation array 190, and inputs data from the X buffer 110 or the like. Furthermore, the selection unit 161 acquires an operation result from the selected floating-point product-sum operation array 170 or the like, and outputs the operation result to the output buffer 150.

The floating-point product-sum operation array 170 is configured by arranging a plurality of product-sum operators 171 that perform product-sum operations of floating-point numbers. A plurality of product-sum operators 171 is arranged in the floating-point product-sum operation array 170 in the drawing. As the product-sum operator 171, for example, a product-sum operator that performs a product-sum operation using a 16-bit half-precision floating-point number can be applied.

The quantized product-sum operation array 180 is configured by arranging a plurality of product-sum operators 172 that perform quantized product-sum operations.

The fixed-point product-sum operation array 190 is configured by arranging a plurality of product-sum operators 173 that perform a product-sum operation of a fixed-point number.

The output buffer 150 holds a result of the product-sum operation. The output buffer 150 outputs held data to the data conversion unit 30. The output buffer 150 can include a semiconductor memory.

The buffer selection unit 50 selects the output buffer 150. The buffer selection unit 50 outputs the data from the selected output buffer 150 to the data conversion unit 30.

The data conversion unit 30 converts the operation result of product-sum calculation into the format of the original data. The data conversion unit 30 outputs the converted data to the region integration unit 19.

The region integration unit 19 integrates the data divided by the region division unit 18. The region integration unit 19 outputs the integrated data to the write control unit 16.

The write control unit 16 writes the data output from the region integration unit 19 in the memory device. The write control unit 16 writes data via the bus interface 17.

### [Configuration of Arithmetic Unit]

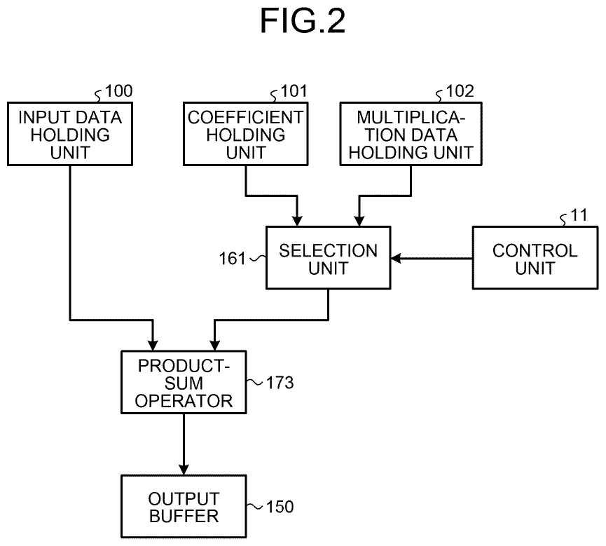

FIG. 2 is a diagram illustrating a configuration example of an arithmetic unit according to the first embodiment of the present disclosure. The drawing is a block diagram of an arithmetic unit representing a portion that performs a convolution operation and an average pooling operation in the neural network circuit 10. The arithmetic unit in the drawing includes an input data holding unit 100, a coefficient holding unit 101, a multiplication data holding unit 102, a selection unit 161, a product-sum operator 173, an output buffer 150, and a control unit 11.

The input data holding unit 100 holds input data of a convolution operation and an average pooling operation. The input data holding unit 100 corresponds to the X buffer 110 and the B buffer 140 described in FIG. 1.

The coefficient holding unit 101 holds coefficients of a filter used for a convolution operation. The coefficient holding unit 101 corresponds to the W buffer 130 described in FIG. 1.

The multiplication data holding unit 102 holds multiplication data. This multiplication data corresponds to the inverse number of the number of elements of a pooling window used for the average pooling operation. The multiplication data holding unit 102 is included in the parameter register 13 of FIG. 1.

The selection unit 161 selects one of the coefficient holding unit 101 and the multiplication data holding unit 102 and outputs data. The selection unit 161 performs selection on the basis of the control of the control unit 11.

The product-sum operator 173 performs a product-sum operation. The product-sum operator 173 in the drawing performs a product-sum operation on the data from the input data holding unit 100 and any one of the coefficient holding unit 101 and the multiplication data holding unit 102 selected by the selection unit 161. The operation result of the product-sum operator 173 is held in the output buffer 150.

The control unit 11 controls a convolution operation and an average pooling operation in the arithmetic unit in the drawing. Specifically, the control unit 11 performs control to input the input data from the input data holding unit 100 and the coefficients held in the coefficient holding unit 101 to the product-sum operator 173 and cause the product-sum operator 173 to perform the product-sum calculation for the convolution operation. The control unit 11 further performs control to input the input data held in the input data holding unit 100 and the multiplier data held in the multiplication data holding unit 102 to the product-sum operator 173 and cause the product-sum operator 173 to perform the product-sum operation for the average pooling operation. The control unit 11 performs control to cause the selection unit 161 to select the coefficient holding unit 101 at the time of the convolution operation, and performs control to cause the selection unit 161 to select the multiplication data holding unit 102 at the time of the average pooling operation. Details of the convolution operation and the average pooling operation will be described next.

### [Convolution Operation]

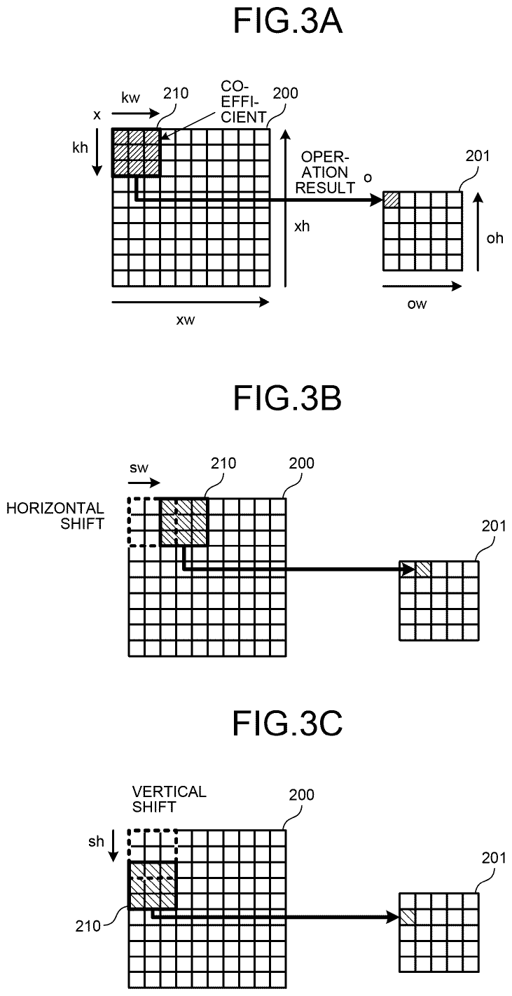

FIGS. 3A to 3C are diagrams illustrating an example of a convolution operation according to an embodiment of the present disclosure. The drawing is a diagram for describing a convolution operation in the arithmetic unit of FIG. 2. Further, the drawing illustrates an example in which the convolution operation is performed on input data 200 and the operation result is stored in output data 201. The input data 200 is, for example, image data configured in a two-dimensional matrix. A rectangle of the input data 200 in the drawing represents an image signal for each pixel. A width in a row direction and a height in a column direction of an input data 200 in the drawings are represented by xw and xh, respectively. The input data 200 is data held in the X buffer 110.

A rectangle of the output data 201 represents a region for storing each operation result. A width in the row direction and a height in the column direction of the output data 201 in the drawing are represented by ow and oh, respectively. The output data 201 is data held in the output buffer 150.

A hatched region in the drawing represents a region of a coefficient 210 of the filter. A width in the row direction (horizontal direction) and a height in the column direction (vertical direction) of the coefficient 210 in the drawing are represented by kw and kh, respectively. A convolution operation is performed on a region of the input data 200 on which the region of the coefficient 210 is superimposed. Specifically, a sum of products of elements of the input data 200 and the coefficient 210 is stored in a corresponding region of the output data 201. The drawing illustrates an example of a case where kw and kh each have a value of 3.

As illustrated in FIG. 3A, a convolution operation is performed in the upper left region of the input data 200. The operation result is stored in the upper left region of the output data 201. In a case where elements of adjacent regions of the output data 201 are calculated, the region of the coefficient 210 is shifted in the horizontal direction and the vertical direction to perform the convolution operation.

FIG. 3B illustrates an example of a case where the region of the coefficient 210 is shifted in the horizontal direction. A shift width in the horizontal direction is represented by sw. The drawing illustrates an example of a case where sw is a value of 2.

FIG. 3C illustrates an example of a case where the region of the coefficient 210 is shifted in the vertical direction. A shift width in the vertical direction is represented by sh. The drawing illustrates an example of a case where sh has a value of 2.

Note that, in FIGS. 3A to 3C, the arithmetic operation of the channel direction is omitted. The convolution operation can be expressed by the following formula.

$$o [ i ] [ j ] = {\sum }_{k = 1}^{kh} {\sum }_{l = 1}^{kw} x [ i \times sh + k ] [ j \times sw + l ] \times w [ k ] [ l ] + b \qquad ( 1 )$$

Here, o represents a result of the convolution operation. i and j are variables indicating a region of the output data 201. i represents a row position, and j represents a column position. x represents the input data 200. sh and sw are the shift widths described above. w represents the coefficient 210. k and l are variables indicating the region of the coefficient 210. k represents a row position, and l represents a column position. b represents a bias value.

The product-sum operator 173 in FIG. 2 executes the operation of Expression (1). Further, x is output from the X buffer 110, sw and sh are output from the parameter register 13, and b is output from the B buffer 140. w is output from the W buffer 130 corresponding to the coefficient holding unit 101. In addition, o is held in the output buffer 150.

### [Average Pooling Operation]

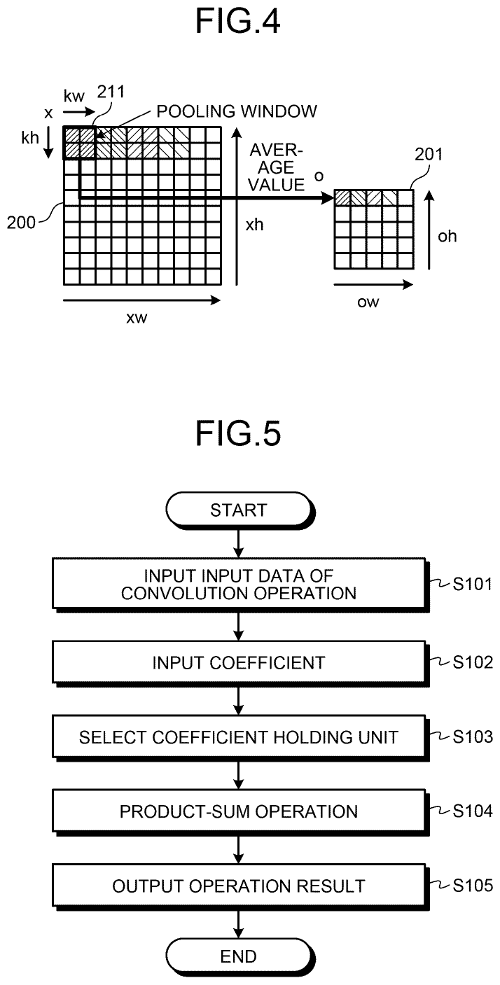

FIG. 4 is a diagram illustrating an example of an average pooling operation according to the embodiment of the present disclosure. The drawing is a diagram for describing an average pooling operation in the arithmetic unit of FIG. 2. The drawing illustrates an example in which the average pooling operation is performed on the input data 200 and the operation result is stored in the output data 201.

A hatched region in the drawing represents a region of a pooling window 211. This pooling window is a region to be pooled in the average pooling operation. A width in the row direction and a height in the column direction of the pooling window 211 in the drawing are represented by kw and kh, respectively. The drawing illustrates an example of a case where kw and kh each have a value of 2.

Also in the average pooling operation, the operation is performed while shifting the pooling window 211 in the horizontal direction and the vertical direction, and the operation result is stored in the corresponding region of the output data 201. The average pooling operation can be expressed by the following formula.

$$o [ i ] [ j ] = \frac{1}{kh \times kw} {\sum }_{k = 1}^{kh} {\sum }_{l = 1}^{kw} x [ i \times kh + k ] [ j \times sw + l ] \qquad ( 2 )$$

As expressed in Expression (2), the average pooling operation is an arithmetic operation of calculating an average of data included in the pooling window 211. The drawing illustrates an example of calculating an average of data of four pixels.

Here, in Expression (1), when sw=kw and sh=kh, the bias value b is set to a value of 0, and all elements of the coefficient 210 are set to 1/(kh x kw), Expression (1) can be expressed as follows.

$$\begin{matrix}o [ i ] [ j ] = {\sum }_{k = 1}^{kh} {\sum }_{l = 1}^{kw} x [ i \times kh + k ] [ j \times kw + l ] \times \frac{1}{kh \times kw} + 0 \\ = \frac{1}{kh \times kw} {\sum }_{k = 1}^{kh} {\sum }_{l = 1}^{kw} x [ i \times kh + k ] [ j \times kw + l ]\end{matrix} \qquad ( 3 )$$

As expressed in Expression (3), the convolution operation of Expression (1) results in the average pooling operation of Expression (2). The average pooling operation can be performed by setting all the elements of the above-described coefficient 210 to 1/(kh x kw), setting the inverse number of the number of elements of the pooling window 211 to the coefficient, and substituting the coefficient into the expression of the convolution operation. Therefore, the product-sum operator 173 used for the convolution operation can be applied to the average pooling operation.

The inverse number of the number of elements of the pooling window 211 is held in the multiplication data holding unit 102 in FIG. 2. By selecting one of the coefficient holding unit 101 and the multiplication data holding unit 102 by the selection unit 161 in FIG. 2, it is possible to cause the product-sum operator 173 to perform the convolution operation and the average pooling operation.

### [Convolution Operation Processing]

FIG. 5 is a diagram illustrating an example of a processing procedure of a convolution operation according to the first embodiment of the present disclosure. The drawing is a flowchart illustrating an example of a processing procedure of a convolution operation in the arithmetic unit of FIG. 2. First, the control unit 11 inputs input data of the convolution operation to the input data holding unit 100 (step S101). Next, the control unit 11 inputs a coefficient to the coefficient holding unit 101 (step S102). Next, the selection unit 161 selects the coefficient holding unit 101 (step S103). Next, the product-sum operator 173 performs a product-sum operation (step S104). Next, the product-sum operator 173 outputs an operation result to the output buffer 150 (step S105). The convolution operation can be performed by the above processing.

### [Average Pooling Operation Processing]

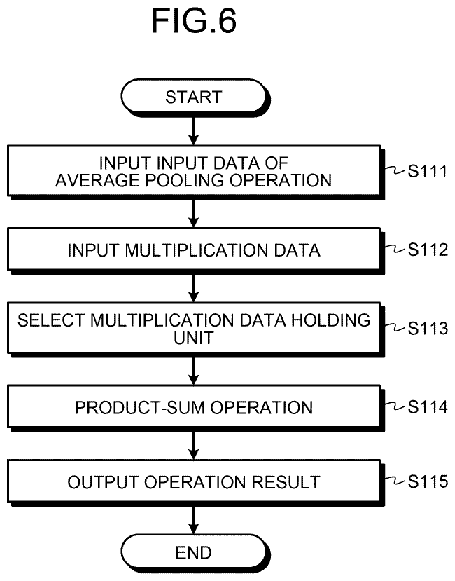

FIG. 6 is a diagram illustrating an example of a processing procedure of an average pooling operation according to the first embodiment of the present disclosure. The drawing is a flowchart illustrating an example of a processing procedure of the average pooling operation in the arithmetic unit of FIG. 2. First, the control unit 11 inputs input data of the average pooling operation to the input data holding unit 100 (step S111). At this time, the control unit 11 inputs a value of 0 to the B buffer 140 that holds the bias value in the input data holding unit 100. Next, the control unit 11 inputs the multiplication data to the multiplication data holding unit 102 (step S112). Next, the selection unit 161 selects the multiplication data holding unit 102 (step S113). Next, the product-sum operator 173 performs a product-sum operation (step S114). Next, the product-sum operator 173 outputs the operation result to the output buffer 150 (step S115). The average pooling operation can be performed by the above processing.

As described in FIGS. 5 and 6, the convolution operation and the average pooling operation can be switched by controlling the selection of the selection unit 161. Note that any value can be input to the multiplication data holding unit 102. Therefore, the product-sum operator 173 can also be used as a multiplier for the value held in the input data holding unit 100 and the value held in the multiplication data holding unit 102.

As described above, the neural network circuit 10 of the first embodiment of the present disclosure uses the product-sum operator 173 used for the convolution operation as a divider for the average pooling operation. This makes it possible to prevent an increase in circuit scale.

### 2. Second Embodiment

The neural network circuit 10 of the first embodiment described above holds multiplication data, which is an inverse number of the number of elements of a pooling window used for the average pooling operation, in the multiplication data holding unit 102. On the other hand, an imaging element 1 of a second embodiment of the present disclosure is different from the above-described first embodiment in generating multiplication data.

### [Configuration of Neural Network Circuit]

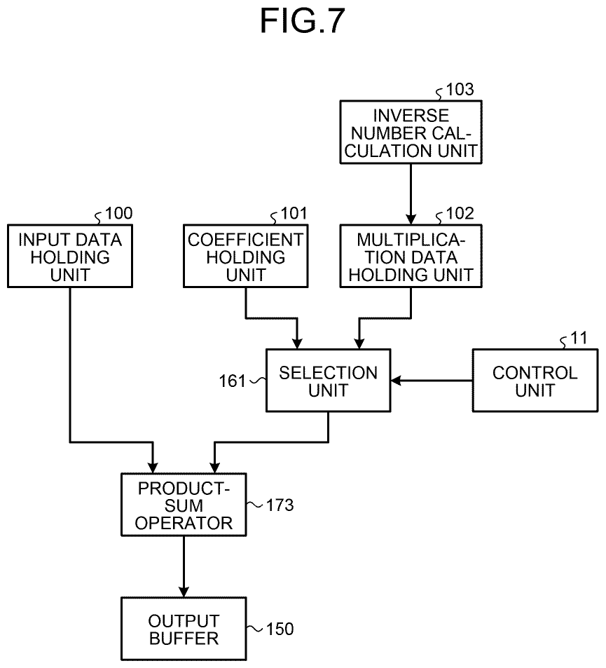

FIG. 7 is a diagram illustrating a configuration example of a neural network circuit according to a second embodiment of the present disclosure. The drawing is a block diagram illustrating a configuration example of the neural network circuit 10 similarly to FIG. 2. The neural network circuit 10 in the drawing is different from the neural network circuit 10 in FIG. 2 in further including an inverse number calculation unit 103.

The inverse number calculation unit 103 calculates the inverse number of the input number of elements of the pooling window. The inverse number calculation unit 103 outputs the calculated inverse number to the multiplication data holding unit 102 and causes the multiplication data holding unit 102 to hold the inverse number.

The configuration of the neural network circuit 10 other than this is similar to the configuration of the neural network circuit 10 according to the first embodiment of the present disclosure, and thus the description thereof will be omitted.

As described above, the neural network circuit 10 of the second embodiment of the present disclosure can simplify the processing of the average pooling operation by arranging the inverse number calculation unit 103 and calculating the inverse number of the number of elements of the pooling window.

Note that the effects described in the present specification are merely examples and are not limited, and other effects may be provided.

Note that the present technology can also have the following configurations.

(1)

A neural network circuit comprising:
a coefficient holding unit that holds a coefficient of a filter used for a convolution operation;
a multiplier data holding unit that holds, as multiplier data, an inverse number of a number of elements of a pooling window used for an average pooling operation;
an input data holding unit that holds input data of the convolution operation and the average pooling operation;
a product-sum operator that performs a product-sum operation; and
a control unit that performs control to input the input data held in the input data holding unit and the coefficient held in the coefficient holding unit to the product-sum operator and cause the product-sum operator to perform a product-sum calculation for the convolution operation, and performs control to input the input data held in the input data holding unit and the multiplier data held in the multiplier data holding unit to the product-sum operator and cause the product-sum operator to perform a product-sum operation for the average pooling operation.
   (2)

The neural network circuit according to the above (1), further comprising
a selection unit that selects one of the coefficient holding unit and the multiplier data holding unit and outputs data, wherein
the control unit further controls the selection unit on a basis of an operation to be performed by the product-sum operator.
   (3)

The neural network circuit according to the above (1) or (2), further comprising an inverse number calculation unit that calculates an inverse number of the number of elements of the pooling window and causes the multiplier data holding unit to hold the inverse number.

(4)

An arithmetic method comprising:
inputting input data held in an input data holding unit that holds input data of a convolution operation and an average pooling operation and a coefficient held in a coefficient holding unit that holds a coefficient of a filter used for the convolution operation to a product-sum operator, and causing the product-sum operator to perform a product-sum calculation for the convolution operation; and
inputting, to the product-sum operator, multiplier data held in a multiplier data holding unit that holds, as multiplier data, the input data held in the input data holding unit and an inverse number of a number of elements of a pooling window used for an average pooling operation, and causing the product-sum operator to perform a product-sum operation for the average pooling operation.

### REFERENCE SIGNS LIST

10 NEURAL NETWORK CIRCUIT
11 CONTROL UNIT
40 BUFFER SELECTION UNIT
100 INPUT DATA HOLDING UNIT
101 COEFFICIENT HOLDING UNIT
102 MULTIPLICATION DATA HOLDING UNIT
103 INVERSE NUMBER CALCULATION UNIT
110 X BUFFER
130 W BUFFER
140 B BUFFER
150 OUTPUT BUFFER
161 SELECTION UNIT
171 to 173 PRODUCT-SUM OPERATOR

1. A neural network circuit comprising:
a coefficient holding unit that holds a coefficient of a filter used for a convolution operation;
a multiplier data holding unit that holds, as multiplier data, an inverse number of a number of elements of a pooling window used for an average pooling operation;
an input data holding unit that holds input data of the convolution operation and the average pooling operation;
a product-sum operator that performs a product-sum operation; and
a control unit that performs control to input the input data held in the input data holding unit and the coefficient held in the coefficient holding unit to the product-sum operator and cause the product-sum operator to perform a product-sum calculation for the convolution operation, and performs control to input the input data held in the input data holding unit and the multiplier data held in the multiplier data holding unit to the product-sum operator and cause the product-sum operator to perform a product-sum operation for the average pooling operation.

2. The neural network circuit according to claim 1, further comprising
a selection unit that selects one of the coefficient holding unit and the multiplier data holding unit and outputs data, wherein
the control unit further controls the selection unit on a basis of an operation to be performed by the product-sum operator.

3. The neural network circuit according to claim 1, further comprising an inverse number calculation unit that calculates an inverse number of the number of elements of the pooling window and causes the multiplier data holding unit to hold the inverse number.

4. An arithmetic method comprising:
inputting input data held in an input data holding unit that holds input data of a convolution operation and an average pooling operation and a coefficient held in a coefficient holding unit that holds a coefficient of a filter used for the convolution operation to a product-sum operator, and causing the product-sum operator to perform a product-sum calculation for the convolution operation; and
inputting, to the product-sum operator, multiplier data held in a multiplier data holding unit that holds, as multiplier data, the input data held in the input data holding unit and an inverse number of a number of elements of a pooling window used for an average pooling operation, and causing the product-sum operator to perform a product-sum operation for the average pooling operation.
